(19) United States
(12) Patent Application Publication
(10) Pub. No.: US 2001/0039086 A1
(43) Pub. Date: Nov. 8, 2001

(54) Semiconductor memory device and method of fabricating the same

(76) Inventor: Natsuki Sato, Tokyo (JP)

Correspondence Address: MCGINN & GIBB, PLLC, 8321 OLD COURTHOUSE ROAD, SUITE 200, VIENNA, VA, 22182-3817, US

(21) Appl. No.: 09/870,783

(22) Filed: Jun. 1, 2001

Related U.S. Application Data
(62) Division of application No. 09/421,064, filed on Oct. 19, 1999.

(30) Foreign Application Priority Data
Oct. 20, 1998 (JP) 10-298336

(51) Int. Cl. H01L 21/8242; H01L 21/20

(52) U.S. Cl. 438/241; 438/253; 438/396

(57) ABSTRACT

There is provided a semiconductor memory device including a first area in which peripheral circuits are to be formed and a second area in which memory cells are to be formed, the semiconductor memory device including (a) at least one capacity electrode formed in the second area, (b) at least one dummy pattern formed in the first area, and (c) an insulating film formed over the first and second areas, the dummy pattern having such a height that a height of the insulating film in the first area is equal to a height of the insulating film in the second area. For instance, the dummy pattern has the same height as a height of the capacity electrode. The semiconductor memory device can have a completely planarized surface.

### BACKGROUND OF THE INVENTION

1. Field of the Invention

The invention relates to a semiconductor memory device and a method of fabricating the same, and more particularly to a dynamic random access memory (DRAM) having a stack type capacity, and a method of fabricating the same.

2. Description of the Related Art

In recent years, DRAM having a stack type capacity has been designed to have a sufficiently great accumulation capacity by designing a thickness of an accumulation electrode to be greater and greater to thereby increase an area of an accumulation electrode. However, a greater thickness of an accumulation electrode is accompanied with a problem that there is unpreferably formed a step between a first area in which peripheral circuits are to be formed and a second area in which memory cells are to be formed.

If a high step exists between the first and second areas, it would not be possible to ensure sufficient focus margin in a photolithography step to be carried out for forming a wiring layer, and hence, it would be quite difficult or almost impossible to properly pattern a wiring layer. This would cause defects such as breakage of a wiring and short-circuit.

In addition, difficulty in properly patterning a wiring layer makes it impossible to select a small design-rule, which causes a problem that a greater design-rule has to be selected. In order to solve this problem, a chip has to be designed larger in a size, resulting in reduction in cost performance.

In order to solve the above-mentioned problems, chemical mechanical polishing (CMP) has been carried out for planarizing a semiconductor device including a high step between the first and second areas.

By applying CMP, a step between the first and second area can be reduced in a height.

Hereinbelow is explained a conventional method of fabricating DRAM. FIGS. 1A to 1C are cross-sectional views of DRAM, each illustrating respective step of a conventional method of fabricating DRAM.

With reference to FIG. 1A, a field oxide film 2 is formed on a p-type semiconductor substrate 1 by thermal oxidation by a thickness of 0.4 μm. The field oxide film 2 defines an area in which a semiconductor memory device is to be fabricated.

Then, n-type polysilicon is deposited all over the substrate 1 by a thickness of 0.2 μm, and is patterned into gate electrodes 4 by photolithography.

Then, the substrate 1 is ion-implanted at a dose of about 5×10¹³ cm⁻² phosphorus in self-align fashion around the gate electrodes 4 and the field oxide film 2, to thereby form n-type diffusion layers 3.

Then, an interlayer insulating film (not illustrated) is deposited over the gate electrodes 4, and thereafter, a contact hole is formed throughout the interlayer insulating film. Then, there is patterned a first wiring layer 5 composed of WSi and having a thickness of 0.2 μm.

Then, a first interlayer insulating film 6 composed of BPSG is deposited over the substrate 1 by a thickness of 0.4 μm. Then, contact holes 13 are formed throughout the first interlayer insulating film 6.

Then, polysilicon is deposited over the first interlayer insulating film 6 by a thickness of 0.8 μm, and is patterned into accumulation electrodes 7.

Then, a capacity insulating film (not illustrated) is deposited over the thus patterned accumulation electrodes 7. Then, polysilicon is deposited over the capacity insulating film by a thickness of 0.2 μm, and is patterned into plate electrodes 8.

Then, a second interlayer insulating film 11 composed of BPSG is deposited by a thickness of 1.5 μm. At this stage, as illustrated in FIG. 1A, there exists a step 15 by which a first area 12A in which peripheral circuits are formed is lower in height than a second area 12B in which memory cells are formed.

Then, the second interlayer insulating film 11 is polished by CMP to thereby planarize the semiconductor device. However, as illustrated in FIG. 1B, the step 15 causes a polishing pressure to be varied in dependence on location where a polishing pad makes contact with the second interlayer insulating film 11 in CMP.

That is, as the second area 12B is polished, the first area 12A which is lower in height than the second area 12B is concurrently polished. Hence, even after CMP has been finished, the step 15 remains as it is, resulting in that the semiconductor device cannot be completely planarized. This is because, since a polishing pad is deformed due to a polishing pressure, a deformed polishing pad makes contact with a large area even in the first area 12A lower than the second area 12B, and hence, the semiconductor device is polished in such a large area.

In addition, since a polishing pressure is high at a boundary between the first and second areas 12A and 12B, a polishing rate at the boundary becomes high. As a result, the underlying plate electrodes 8 are exposed at the boundary 17 (see FIG. 1C), which might cause a problem that

Then, as illustrated in FIG. 1C, a second wiring layer 16 is formed on the second interlayer insulating layer 11. The second wiring layer 16 is composed of aluminum, for instance. Thus, there is completed a semiconductor device.

However, reviewing the thus fabricated semiconductor device as a final product, the step 15 still remains in the first area 12A even after CMP, since the first area 12A is concurrently polished together with the second area 12B. Thus, the semiconductor device is not completely planarized.

In addition, since a polishing rate is high at the boundary between the first and second areas 12A and 12B, the underlying plate electrodes 8 are exposed at the boundary 17. Such exposure of the plate electrodes 8 might cause defects such as short-circuit between the second wiring layer 16 and the plate electrodes 8. As a result, it would be difficult to pattern the second wiring layer 16 into minute patterns.

Thus, the conventional method is accompanied with problems that since a resultant semiconductor device cannot be completely planarized, the second interlayer insulating layer 11 has a varying thickness dependent on location with the result that the second wiring layer 16 cannot be properly patterned, which would cause reduction in fabrication yield, and that a difference in a polishing rate causes the plate electrodes 8 to be exposed, resulting in that the second wiring layer 16 might be short-circuited with the plate electrodes 8.

Japanese Unexamined Patent Publication No. 3-82077 has suggested a semiconductor memory device including a semiconductor substrate, a plurality of memory cells arranged in an array and each including an accumulation capacitor having a multi-layered electrode, and a block composed of the same material as a material of which any one of electrodes constituting the accumulation capacitor is composed, and having a sidewall inclined outwardly of the memory cell array. The block is formed along a periphery of the memory cell array.

Japanese Unexamined Patent Publication No. 4-335569 has suggested a semiconductor device including a substrate, an interlayer insulating film having a step at which the interlayer insulating film is divided into lower and higher portions, a first electrically conductive wiring layer formed on the lower portion of the interlayer insulating film, and a second electrically conductive wiring layer formed on the higher portion of the interlayer insulating film, a dummy wiring layer located in the vicinity of the step and just below the first electrically conductive wiring layer, and having a height almost the same as the step, and an electrically conductive layer extending from the dummy wiring layer to a surface of the substrate. The second electrically conductive wiring layer makes electrical contact with a portion of the electrically conductive layer located at a surface of the substrate, through a contact hole formed throughout the interlayer insulating film. The first electrically conductive wiring layer makes electrical contact with a portion of the electrically conductive layer located just above the dummy wiring layer, through a contact hole formed throughout the interlayer insulating film.

Japanese Unexamined Patent Publication No. 5-275649 has suggested a semiconductor memory device including a word line, a lower interlayer insulating layer, an accumulation electrode constituting a capacitor, an upper interlayer insulating layer, and a metal wiring layer deposited in this order in a memory cell array area on a semiconductor substrate. The wiring layer extends beyond the memory cell array area. At least one of a spacer wiring formed of a common layer to the word line and a spacer electrode formed of a common layer to the accumulation electrode is located externally adjacent to the memory cell array.

Japanese Unexamined Patent Publication No. 6-216332 has suggested a semiconductor memory device in which a dummy word line and/or a dummy capacitor electrode are positioned adjacent to memory cell array to thereby reduce a step formed between a memory cell array area and a peripheral circuit area. An inclination from the memory cell array area to the peripheral circuit area may be decreased.

Japanese Patent No. 2519569 (Japanese Unexamined Patent Publication No. 4-10651) has suggested a semiconductor memory device including a memory cell array area and a peripheral circuit area located adjacent to the memory cell array area, characterized by a first interlayer insulating film covering the peripheral circuit area therewith, a second interlayer insulating film covering both the memory cell array area and the peripheral circuit area therewith, and a standing wall formed in a boundary area located between the memory cell array area and the peripheral circuit area.

The above-mentioned problems in the conventional method remain unsolved even by the semiconductor devices suggested in the above-mentioned Publications.

### SUMMARY OF THE INVENTION

It is an object of the present invention to provide a semiconductor memory device which has a completely planarized surface, and hence, makes it possible to properly pattern an upper wiring layer.

It is also an object of the present invention to provide a method of fabricating such a semiconductor memory device.

In one aspect of the present invention, there is provided a semiconductor memory device including a first area in which peripheral circuits are to be formed and a second area in which memory cells are to be formed, the semiconductor memory device including a dummy pattern formed in the first area to thereby substantially equalize a height of the first area to a height of the second area.

There is further provided a semiconductor memory device including a first area in which peripheral circuits are to be formed and a second area in which memory cells are to be formed, the semiconductor memory device including (a) at least one capacity electrode formed in the second area, (b) at least one dummy pattern formed in the first area, and (c) an insulating film formed over the first and second areas, the dummy pattern having such a height that a height of the insulating film in the first area is equal to a height of the insulating film in the second area.

For instance, the dummy pattern may be designed to have the same height as a height of the capacity electrode.

For instance, if the capacity electrode is comprised of an accumulation electrode and a plate electrode covering the accumulation electrode therewith, the dummy pattern is comprised of a dummy accumulation electrode having the same height as a height of the accumulation electrode and a dummy plate electrode covering the dummy accumulation electrode therewith and having the same thickness as a thickness of the plate electrode.

The semiconductor memory device may include two or more dummy patterns.

In another aspect of the present invention, there is provided a method of fabricating a semiconductor memory device including a first area in which peripheral circuits are to be formed and a second area in which memory cells are to be formed, the method including the step of forming a dummy pattern in the first area so that a height of the first area is substantially equal to a height of the second area.

There is further provided a method of fabricating a semiconductor memory device including a first area in which peripheral circuits are to be formed and a second area in which memory cells are to be formed, including the steps of (a) forming at least one capacity electrode in the second area, (b) forming at least one dummy pattern in the first area, and (c) forming an insulating film over the first and second areas, the dummy pattern being formed to have such a height in the step (b) that a height of the insulating film in the first area is equal to a height of the insulating film in the second area.

The method may further include the step of planarizing the insulating film.

It is preferable that the dummy pattern is formed to have the same height as a height of the capacity electrode in the step (b).

When the capacity electrode is comprised of an accumulation electrode and a plate electrode covering the accumulation electrode therewith, the dummy pattern may be comprised of a dummy accumulation electrode having the same height as a height of the accumulation electrode and a dummy plate electrode covering the dummy accumulation electrode therewith and having the same thickness as a thickness of the plate electrode, and wherein the accumulation electrode and the dummy accumulation electrode are formed in a common step and the plate electrode and the dummy plate electrode are formed in a common step.

Two or more dummy patterns may be formed in the step (b).

The advantages obtained by the aforementioned present invention will be described hereinbelow.

A step such as the step 15 shown in FIG. 1A, which cannot be eliminated even by planarizing, is caused by a difference between the first and second areas as to whether a capacity electrode such as the accumulation electrode 7 and the plate electrode 8 is formed or not. Hence, in accordance with the present invention, a dummy pattern constituted of a capacity electrode is formed also in the first area.

As a result, an insulating film in the first area can be equalized in height to an insulating film in the second area. That is, a step can be eliminated, which ensures a polishing pressure in CMP can be uniformized in the first and second areas. Hence, an insulating film can be polished by CMP with a uniform polishing pressure, resulting in that the insulating film is uniform in height after CMP has been finished.

The dummy pattern may be designed not to be located in an area where a contact hole for electrically connecting an upper wiring layer to a lower wiring layer is to be formed.

Thus, in accordance with the above-mentioned present invention, a semiconductor memory device can be completely planarized by CMP, for instance. A step such as the step 15 shown in FIG. 1A is not formed in the first area. Hence, a polishing pressure can be uniformized in CMP independently of location at a surface of a semiconductor memory device. Hence, an upper wiring pattern can be properly patterned, resulting in that a fabrication yield can be enhanced.

The capability of properly patterning an upper wiring layer would make it possible to apply smaller design-rule to a semiconductor device, resulting in that a semiconductor device can be fabricated in a smaller size, and hence, cost performance can be enhanced accordingly.

In addition, it is possible to avoid an underlying layer such as the plate electrodes 8 as illustrated in FIG. 1C from being exposed, which would ensure enhancement in a fabrication yield of a semiconductor memory device.

The above and other objects and advantageous features of the present invention will be made apparent from the following description made with reference to the accompanying drawings, in which like reference characters designate the same or similar parts throughout the drawings.

### BRIEF DESCRIPTION OF THE DRAWINGS

FIGS. 1A to 1C are cross-sectional views of a semiconductor memory device, each illustrating respective step of a conventional method of fabricating a semiconductor memory device.

FIGS. 2A to 2C are cross-sectional views of a semiconductor memory device, each illustrating respective step of a method of fabricating a semiconductor memory device in accordance with a preferred embodiment of the present invention.

### DESCRIPTION OF THE PREFERRED EMBODIMENT

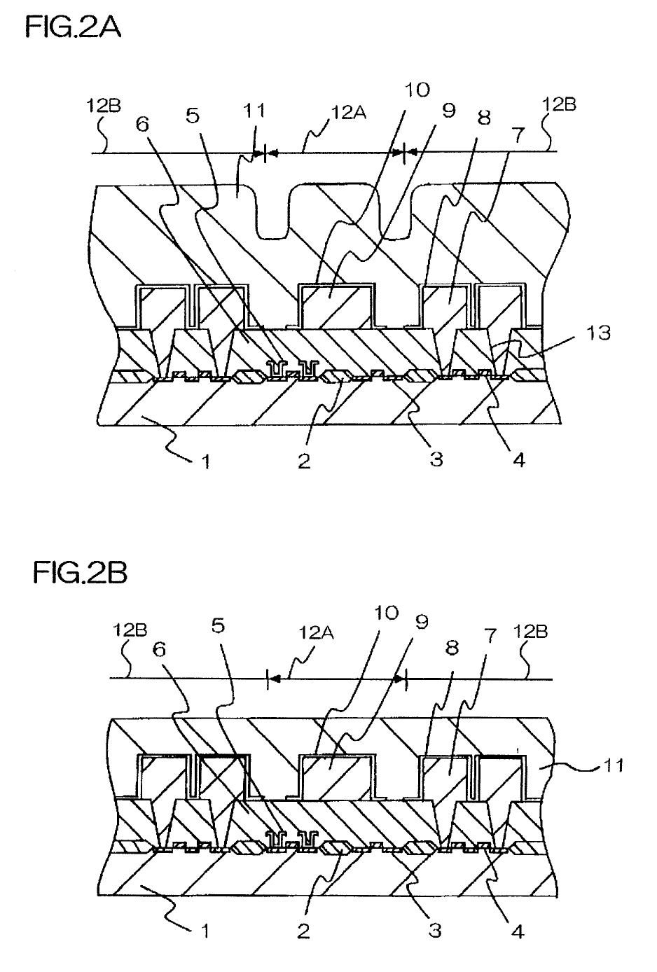

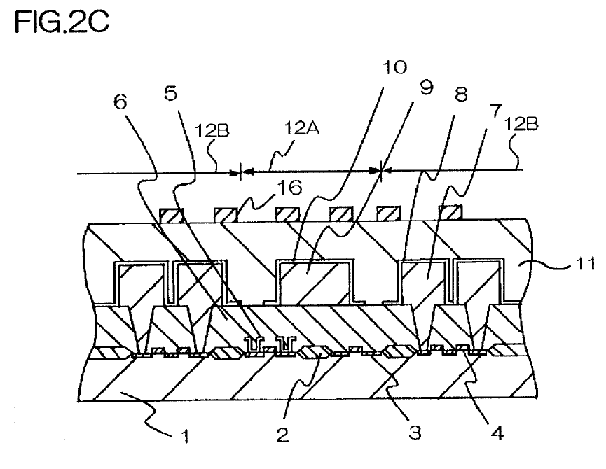

Hereinbelow is explained a method of fabricating DRAM in accordance with a preferred embodiment of the present invention. FIGS. 2A to 2C are cross-sectional views of DRAM, each illustrating respective step of a method of fabricating DRAM.

The illustrated DRAM includes a first area 12A in which peripheral circuits are to be formed and a second area 12B in which memory cells are to be formed.

With reference to FIG. 2A, a field oxide film 2 is formed on a p-type semiconductor substrate 1 by thermal oxidation by a thickness of 0.4 μm. An area surrounded by the adjacent field oxide film 2 defines an area in which a semiconductor memory device is to be fabricated.

Then, n-type polysilicon is deposited all over the substrate 1 by a thickness of 0.2 μm, and is patterned into gate electrodes 4 by photolithography.

Then, the substrate 1 is ion-implanted at a dose of about 5×10¹³ cm⁻² phosphorus in self-align fashion around the gate electrodes 4 and the field oxide film 2, to thereby form n-type diffusion layers 3 at a surface of the substrate 1.

Then, an interlayer insulating film (not illustrated) is deposited over the gate electrodes 4, and thereafter, a contact hole is formed throughout the interlayer insulating film. Then, there is patterned a first wiring layer 5 composed of WSi and having a thickness of 0.2 μm.

Then, a first interlayer insulating film 6 composed of BPSG is deposited over the substrate 1 by a thickness of 0.4 μm. Then, contact holes 13 are formed throughout the first interlayer insulating film 6.

Then, polysilicon is deposited over the first interlayer insulating film 6 by a thickness of 0.8 μm. Then, the polysilicon is patterned into a dummy accumulation electrode 9 in the first area 12A in which it is not necessary to form an accumulation electrode 7, as well as into accumulation electrodes 7 in the second area 12B.

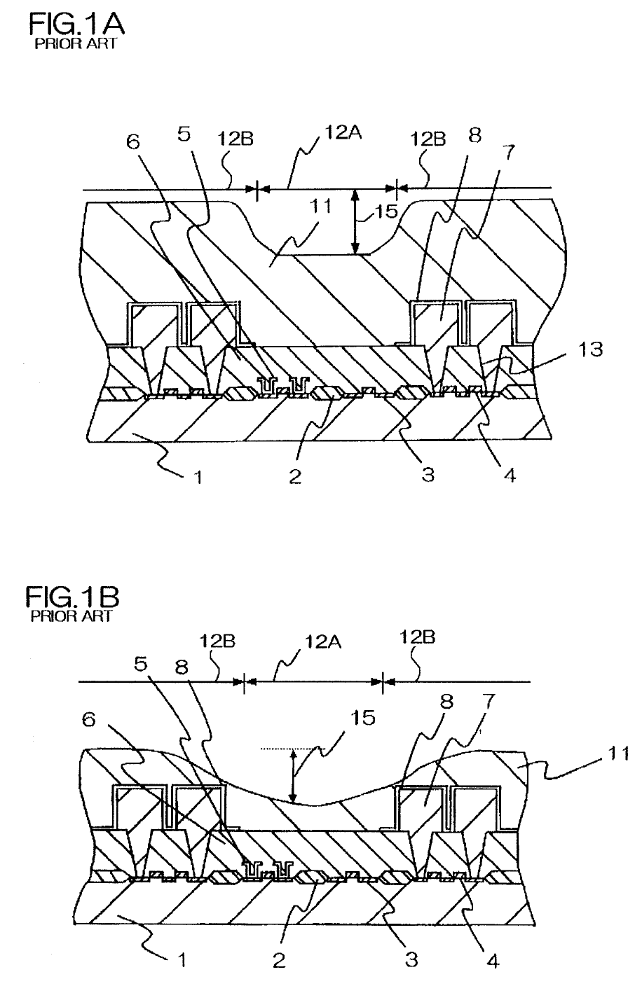

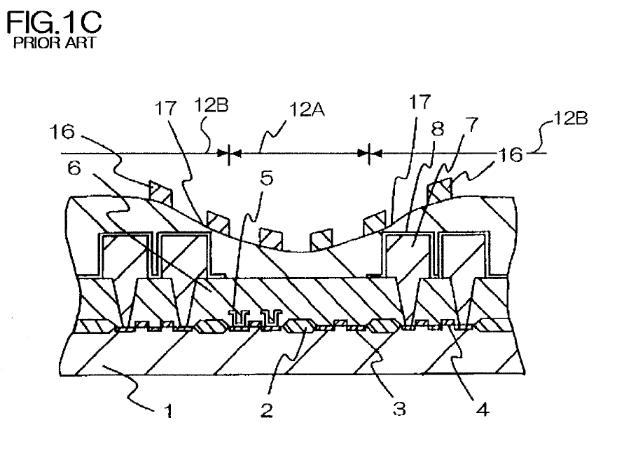

The dummy accumulation electrode 9 is designed to be large or small in size in dependence on a size of a peripheral circuit to be formed in the first area 12A. Though only one dummy accumulation electrode 9 is illustrated in FIG. 2A, two or more dummy accumulation electrodes 9 may be formed. As mentioned later, the dummy accumulation electrode 9 makes it possible to eliminate a step such as the step 15 shown in FIG. 1A, by which the first area 12A is lower in height than the second area 12B.

Since there may be formed a contact hole or contact holes in the first area 12A for electrically connecting the n-type diffusion layer 3 to a later mentioned second wiring layer 16, it should be noted that the dummy accumulation electrode 9 is not formed at a location where the contact hole is to be formed.

Then, a capacity insulating film (not illustrated) is deposited over the accumulation electrodes 7 and the dummy accumulation electrode 9. Then, polysilicon is deposited over the capacity insulating film by a thickness of 0.2 μm, and is patterned into plate electrodes 8. The polysilicon covering the dummy accumulation electrode 9 therewith is also patterned into a plate electrode 10. Thus, the first area 12A can have the same height as a height of the second area 12B.

Then, a second interlayer insulating film 11 composed of BPSG is deposited by a thickness of 1.5 μm, covering the accumulation electrodes 7 and the plate electrodes 8 therewith in the second area 12B, as well as covering the dummy accumulation electrode 9 and the plate electrode 10 therewith in the first area 12A.

Then, the second interlayer insulating film 11 is polished by CMP to thereby planarize DRAM.

The planarized DRAM is illustrated in FIG. 2B. By planarizing DRAM, it is possible to equalize the first area 12A in height to the second area 12B.

Then, as illustrated in FIG. 2C, a second wiring layer 16 is formed on the planarized second interlayer insulating layer 11. The second wiring layer 16 is composed of aluminum, for instance. Thus, there is completed DRAM in accordance with the embodiment.

Since DRAM is completely planarized, it is possible to properly pattern the second wiring layer 16 even into a minute pattern, which would ensure no risk of short-circuit between the second wiring layer 16 and the plate electrodes 8.

It should be noted that voltages of the dummy accumulation electrode 9 and the dummy plate electrode 10 might be fixed to a power source voltage, a grounded voltage (GND), or a half of a power source voltage.

While the present invention has been described in connection with certain preferred embodiments, it is to be understood that the subject matter encompassed by way of the present invention is not to be limited to those specific embodiments. On the contrary, it is intended for the subject matter of the invention to include all alternatives, modifications and equivalents as can be included within the spirit and scope of the following claims.

The entire disclosure of Japanese Patent Application No. 10-298336 filed on Oct. 20, 1998 including specification, claims, drawings and summary is incorporated herein by reference in its entirety.

What is claimed is:

1. A semiconductor memory device including a first area in which peripheral circuits are to be formed and a second area in which memory cells are to be formed, said semiconductor memory device comprising a dummy pattern formed in said first area to thereby substantially equalize a height of said first area to a height of said second area.

2. A semiconductor memory device including a first area in which peripheral circuits are to be formed and a second area in which memory cells are to be formed, said semiconductor memory device comprising:
(a) at least one capacity electrode formed in said second area;
(b) at least one dummy pattern formed in said first area; and
(c) an insulating film formed over said first and second areas,
said dummy pattern having such a height that a height of said insulating film in said first area is equal to a height of said insulating film in said second area.

3. The semiconductor memory device as set forth in claim 2, wherein said dummy pattern has the same height as a height of said capacity electrode.

4. The semiconductor memory device as set forth in claim 2, wherein said capacity electrode is comprised of an accumulation electrode and a plate electrode covering said accumulation electrode therewith, and said dummy pattern is comprised of a dummy accumulation electrode having the same height as a height of said accumulation electrode and a dummy plate electrode covering said dummy accumulation electrode therewith and having the same thickness as a thickness of said plate electrode.

5. The semiconductor memory device as set forth in claim 2, wherein said semiconductor memory device includes two or more dummy patterns.

6. A method of fabricating a semiconductor memory device including a first area in which peripheral circuits are to be formed and a second area in which memory cells are to be formed, comprising the step of forming a dummy pattern in said first area so that a height of said first area is substantially equal to a height of said second area.

7. A method of fabricating a semiconductor memory device including a first area in which peripheral circuits are to be formed and a second area in which memory cells are to be formed, comprising the steps of:
(a) forming at least one capacity electrode in said second area;
(b) forming at least one dummy pattern in said first area; and
(c) forming an insulating film over said first and second areas,
said dummy pattern being formed to have such a height in said step (b) that a height of said insulating film in said first area is equal to a height of said insulating film in said second area.

8. The method as set forth in claim 7, further comprising the step of planarizing said insulating film.

9. The method as set forth in claim 7, wherein said dummy pattern is formed to have the same height as a height of said capacity electrode in said step (b).

10. The method as set forth in claim 7, wherein said capacity electrode is comprised of an accumulation electrode and a plate electrode covering said accumulation electrode therewith, and said dummy pattern is comprised of a dummy accumulation electrode having the same height as a height of said accumulation electrode and a dummy plate electrode covering said dummy accumulation electrode therewith and having the same thickness as a thickness of said plate electrode, and wherein said accumulation electrode and said dummy accumulation electrode are formed in a common step and said plate electrode and said dummy plate electrode are formed in a common step.

11. The method as set forth in claim 7, wherein two or more dummy patterns are formed in said step (b).
